(19) United States
(12) Patent Application Publication
(10) Pub. No.: US 2014/0123737 A1
(43) Pub. Date: May 8, 2014

(54) Apparatus for Detecting Particles in a Fluid and a Method of Fabricating the Same

(71) Applicant: AGENCY FOR SCIENCE, TECHNOLOGY AND RESEARCH, Singapore (SG)

(72) Inventors: Tze Sian Pui, Singapore (SG); Abdur Rub Abdur Rahman, Singapore (SG)

(73) Assignee: Agency for Science, Technology and Research, Singapore (SG)

(21) Appl. No.: 13/670,821

(22) Filed: Nov. 7, 2012

(51) Int. Cl. G01N 15/10; H05K 3/30; H05K 3/00

(52) U.S. Cl. CPC G01N 15/1031; H05K 3/00; H05K 3/30
USPC 73/61.71; 29/846; 29/832

(57) ABSTRACT

An apparatus for detecting particles in a fluid is provided including a substrate, a plurality of channel through holes extending through the substrate, wherein the channel through holes are configured to carry the fluid, a plurality of circuits monolithically integrated with the substrate, wherein each circuit of the plurality of circuitries is arranged adjacent a respectively assigned channel through hole, each circuit including a detection electrode and an control circuit coupled to the detection electrode and configured to control access to the detection electrode, wherein each detection electrode is positioned relative to the respectively assigned channel through hole such at least one electrical property of the fluid flowing through the channel through hole can be detected.

### TECHNICAL FIELD

Various aspects of this disclosure relate to apparatus for detecting particles in a fluid.

### BACKGROUND

Various aspects of this disclosure relate to an apparatus for detecting particles in a fluid. Coulter counters are instruments designed to count particles of various shapes and sizes. They have been used for profiling cells, bacteria, viruses and other biological and non-biological entities over the past several decades. In a Coulter counter, particles are flowed through a confined space where an electric field exists between two electrodes. Any disturbance in this field by the traversing particle in the orifice is picked up by the sensing electronics.

2010 saw the commercialization of a handheld coulter counter. This major development in an age old technique demonstrates the emerging needs and market opportunities, provided significant advances in technology can be accomplished such as miniaturization, throughput and multiplexing.

A significant limitation of the conventional coulter devices is their low throughput and low sample volume. In the handheld coulter device, 50 μl volume is forced through a single orifice for particle analysis. Large bulky systems with multiple detection systems are required in cases which require higher through put. The large bulky systems are inconvenient to set up and carry around.

### SUMMARY

Various aspects of this disclosure provide an improved apparatus that is able to address at least partially the abovementioned challenges.

In various embodiments, an apparatus for detecting particles in a fluid including a substrate, a plurality of channel through holes extending through the substrate, wherein the channel through holes are configured to carry the fluid, a plurality of circuits monolithically integrated with the substrate, wherein each circuit of the plurality of circuitries is arranged adjacent a respectively assigned channel through hole, each circuit including a detection electrode and an control circuit coupled to the detection electrode and configured to control access to the detection electrode, wherein each detection electrode is positioned relative to the respectively assigned channel through hole such at least one electrical property of the fluid flowing through the channel through hole can be detected.

In various embodiments, a method of fabricating an apparatus for detecting particles in a fluid including providing a substrate, forming a plurality of channel through holes extending through the substrate, wherein the channel through holes are configured to carry the fluid, forming a plurality of circuits monolithically integrated with the substrate, wherein each circuit of the plurality of circuitries is arranged adjacent a respectively assigned channel through hole, each circuit including a detection electrode and an control circuit coupled to the detection electrode and configured to control access to the detection electrode, wherein each detection electrode is positioned relative to the respectively assigned channel through hole such at least one electrical property of the fluid flowing through the channel through hole can be detected.

### BRIEF DESCRIPTION OF THE DRAWINGS

The invention will be better understood with reference to the detailed description when considered in conjunction with the non-limiting examples and the accompanying drawings, in which:

FIG. 1 shows the top planar view of an apparatus according to various embodiments.

FIG. 2 shows a side cross sectional view of a portion of the apparatus shown in FIG. 1 according to various embodiments.

FIG. 3A shows a flow schematic illustrating a method to fabricate the apparatus for detecting particles according to various embodiments. FIG. 3B shows a scanning electron microscopy image of a channel through hole extending across the silicon substrate and the overlying layer.

FIG. 4 is a graph plotting the relative resistance change against the ratio of the diameter of the particle and the diameter of the channel.

FIG. 5 is a graph plotting the relative resistance change against the ratio of the aspect ratio of the channel through hole (indicated as a ratio of the length of the channel through hole to the diameter of the channel through hole).

FIG. 6A is a plot showing pulse profiles of particles consisting of a single entity, two entities and three entities. FIG. 6B is a plot showing pulse profiles of particles having different sizes. FIG. 6C is a plot showing pulse profiles of particles in fluids of different pressures.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, and logical changes may be made without departing from the scope of the invention. The various embodiments are not necessarily mutually exclusive, as some embodiments can be combined with one or more other embodiments to form new embodiments.

In order that the invention may be readily understood and put into practical effect, particular embodiments will now be described by way of examples and not limitations, and with reference to the figures.

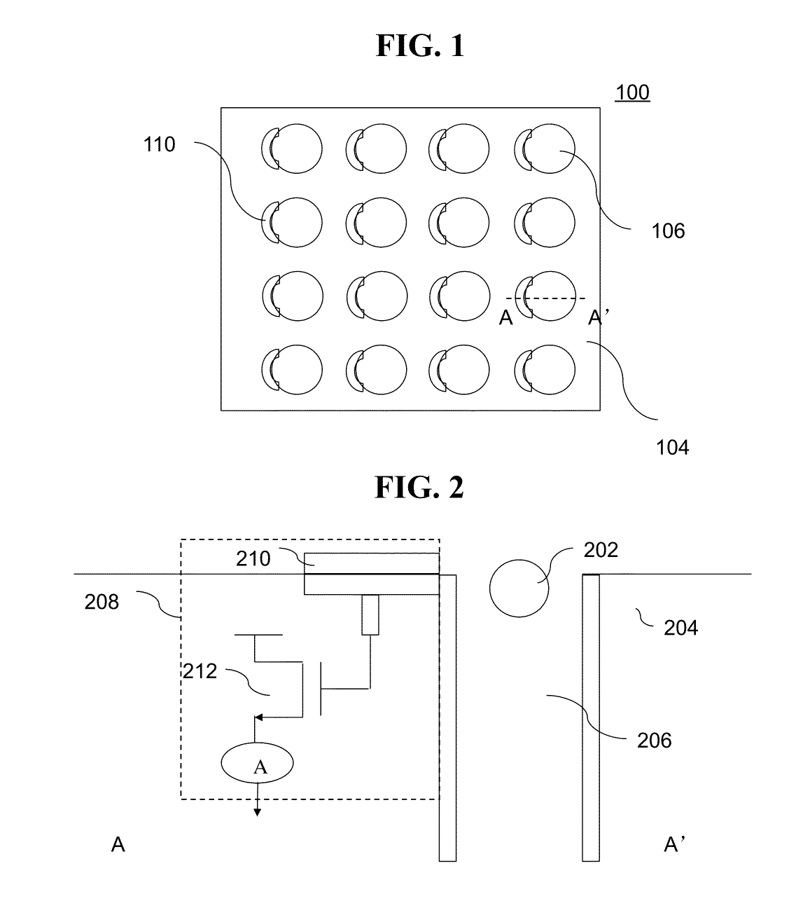

FIG. 1 shows a top planar view of an apparatus 100 according to various embodiments. FIG. 1 shows the apparatus 100 with a plurality of channel through holes 106 extending through a substrate 104, each through hole 106 having an assigned detection electrode 110. The line AA′ corresponds to the side view shown in FIG. 2.

FIG. 2 shows a side cross sectional view of a portion of the apparatus shown in FIG. 1 according to various embodiments for detecting particles 202 in a fluid including a substrate 204, a plurality of channel through holes 206 extending through the substrate 204, wherein the channel through holes 206 are configured to carry the fluid, a plurality of circuits 208 monolithically integrated with the substrate 204, wherein each circuit of the plurality of circuitries 208 is arranged adjacent a respectively assigned channel through hole 206, each circuit 208 including a detection electrode 210 and an control circuit 212 coupled to the detection electrode 210 and configured to control access to the detection electrode 210, wherein each detection electrode 210 is positioned relative to the respectively assigned channel through hole 206 such at least one electrical property of the fluid flowing through the channel through hole 206 can be detected.

In other words, an apparatus is provided having a plurality of channel through holes 206. Each channel through hole 206 is associated with a corresponding circuit 208. The circuits 208 are integrally formed with the substrate 204 such that the circuits 208 and the substrate 204 form a monolithic structure. Advantageously, this helps to reduce the foot print occupied by the circuits, which helps to reduce the size of the apparatus. In addition, this allows for a lower noise to signal ratio compared to a device in which the circuits and the substrate are not integrated. Each circuit includes a detection electrode 210 and a control circuit 212.

The plurality of channel through holes 206 may allow for multiplexing. This may lead to an improved apparatus capable of processing a relatively higher volume of throughput in a relatively small area.

During operation, the fluid carrying particles flows through the channel through holes 206. Each circuit 208 is configured to detect an electrical property of the fluid passing through the assigned channel through hole 206. When a particle 202 passes through the assigned channel through hole 206, the electrical property of the fluid detected by the detection electrode 210 changes as the particles 202 has an electrical property that is different from that of the rest of the fluid. The change in electrical property of the fluid detected by the detection electrode 210 causes a change or disturbance in current flowing through the control circuits 212. The control circuits 212 may then send signals to a processor. The processed results may then be sent to a display. The control circuits 212 may also send the signal directly to a display. The signals may be read from the control circuits 212 in parallel.

In various embodiments, the channel through holes 206 may extend substantially perpendicularly from a first surface of the substrate 204 to a second surface of the substrate opposite the first surface of the substrate 204. This may reduce the foot print occupied by the channel through holes and allows for a smaller apparatus. The channel through holes 206 may be cylindrical or of any other shape.

The channel through holes 206 may extend directly from the first surface of the substrate 204 to the second surface of the substrate 204 opposite the first surface of the substrate 204. Alternatively, the channel through holes 206 may include several channel segments to form the channel through holes 206 extending through the substrate.

In various embodiments, the electrical property is an electrical property representative of an amount of the particles 202 to be detected in the fluid. In this manner, the amount of particles 202 present in the fluid can be known by monitoring the electrical property. This allows the user to know the number of particles 202 in the fluid at the time in a fast and convenient manner.

In various embodiments, the electrical property is an electrical property representative dependent on the type of particles 202 to be detected in the fluid. One type of particles may provide a different electrical property from another type of particles. By monitoring the electrical property, the user may know the type of particles 202 in the fluid in a fast and convenient manner.

In various embodiments, the electrical property is an electrical property representative dependent on size of particles 202 to be detected in the fluid. Particles 202 having different sizes may have different electrical properties. By monitoring the electrical property, the user may know the size of particles 202 in the fluid in a fast and convenient manner. In the event that the particle 202 is an assembly of more than one entity (such as a group of biological cells joined together), the electrical property may be an electrical property representative dependent on the number of entities making up each particle to be detected in the fluid.

In various embodiments, the particles are biological entities. Biological entities may include biological cells, deoxyribonucleic acids (DNAs), biological molecules, proteins, etc.

In various embodiments, the particles are non biological entities or inorganic material such as polymer microspheres and beads.

The substrate 204 may include silicon or other semiconducting or dielectric materials or any other suitable materials or combinations of materials.

In various embodiments, each control circuit 212 may include a transistor coupled to the respective detection electrode 210 such that a change of the at least one electrical property of the fluid flowing through the channel through hole causes a change of a current flow through the transistor.

In various embodiments, each control circuit 212 may include a transistor coupled to the respective detection electrode such that a change of the at least one electrical property of the fluid flowing through the channel through hole 206 causes a disturbance of the current flow through the transistor. For instance, the particles may be indicated as current pulses in the current flow. Properties such as size, types or number of entities of each particle may have an effect on the electrical property of the fluid. Different particles may result in different current pulses having different pulse height and/or pulse width.

In various embodiments, each disturbance of the current flow through the transistor is representative for a predetermined number of particles in the fluid. In other words, the particles in the fluid can be counted by monitoring the number of disturbances of the current flow through the transistors.

For instance, the circuit 208 may detect a resistance of the fluid at a certain point or portion along the assigned channel through hole 206. When a particle 202 passes through the assigned channel through hole 206, the resistance detected by the detection electrode 210 changes as the particles 202 has a resistance that is different from rest of the fluid. The change in resistance causes a change in a current flowing through the control circuit 212 or transistor. In this manner, the detection of the particles is achieved by monitoring the change in current flowing through the control circuit 212 or transistor.

In various embodiments, the transistor may include a control terminal (e.g. a gate terminal), a first controlled terminal (e.g. a source terminal) and a second controlled terminal (e.g. a drain terminal), wherein the control terminal of the transistor is electrically connected to the detection electrode.

The transistor may be a field effect transistor such as a metal oxide field effect transistor.

In various embodiments, the metal oxide field effect transistor may include a control terminal, a first controlled terminal and a second controlled terminal, wherein the control terminal of the metal oxide field effect transistor is electrically connected to the detection electrode. In this case, a first voltage is applied between the two controlled terminals (i.e. the source and drain terminals) such that a current flows between the two controlled terminals. A second voltage may be applied through the assigned channel through hole between the detection electrode and a coupling electrode to measure a change in potential difference caused by the resistance change of the fluid passing through the assigned channel through hole. When a particle passes through the assigned channel through hole, the change in potential difference detected by the detection electrode causes a voltage change at the control terminal (i.e. the gate terminal) of the metal oxide field effect transistor. The current flowing between the two controlled terminals (i.e. the source and drain terminals) due to the first voltage applied between the two controlled terminals is disturbed. In this manner, the detection of the particles passing through the assigned channel through hole is achieved by monitoring the disturbance in the current flowing through the transistor between the two controlled terminals. The metal oxide field effect transistor may operate in the linear or saturation region for such a detection scheme.

For instance, a potential voltage may be applied to the detection electrode 210 through a current passing through the control circuit 212 or transistor and detection electrode 210 to generate an electric field passing through a certain point or portion along the assigned channel through hole. When a particle passes through the point or portion along the assigned channel through hole, the electric field is disturbed due to a difference in permittivity between the particle and the rest of the fluid. This causes a disturbance in the current flowing through detection electrode 210 and the control circuit 212 or transistor. In this manner, the detection of the particles is achieved by monitoring the disturbance in current flowing through the control circuit 212 or transistor.

In various embodiments, the transistor may include a control terminal, a first controlled terminal and a second controlled terminal, wherein the first controlled terminal of the transistor is electrically connected to the detection electrode.

The transistor may be a field effect transistor such as a metal oxide field effect transistor.

In this case, a current passes through the metal oxide field effect transistor such that the detection electrode 210 is of a potential voltage. The potential voltage applied to the detection electrode 210 causes an electric field passing through a point or portion along the assigned channel through hole. When a particle passed through the point or portion along the assigned channel through hole, the electric field is disturbed due to a difference in permittivity between the particle and the rest of the fluid. This causes a disturbance in the current flowing through the metal oxide field effect transistor and the detection electrode 210. In this manner, the detection of the particles is achieved by monitoring the disturbance in current flowing through the metal oxide field effect transistor. In various embodiments, this method may not require a pair of electrode to be positioned around the assigned through hole and requires only a single detection electrode 210 for each assigned through hole. This may further reduce the area footprint of the apparatus. The metal oxide field effect transistor may operate in the linear region for such a detection scheme.

In various embodiments, the detection electrode may include a first layer and a second layer stacked above one another. The first layer may be aluminum and the second layer may be gold or platinum. As aluminum adheres well to silicon, it is used as an adhesion layer on a silicon substrate. However, as aluminum oxidizes easily in air to form a layer of aluminum oxide which will decrease the detection sensitivity, a second layer such as gold or platinum is deposited on top of the aluminum layer to reduce or prevent the formation of aluminum oxide.

In various embodiments, the plurality of channel through holes are arranged in a two dimensional array along the substrate. This may allow greater scaling of the two dimensional array compared to, for instance, a one dimensional array. In various embodiments, this may allow the array to occupy a smaller footprint so that the apparatus is able to achieve a higher number of channel through holes 206 per unit area.

The channel through holes 206 in the array may be regularly spaced from one another.

The channel through holes 206 in the array in the two dimensional array may form a regular square shape, a regular rectangular shape, a diamond shape etc.

A method of fabricating an apparatus according to various embodiments for detecting particles in a fluid includes providing a substrate, including providing a substrate, forming a plurality of channel through holes extending through the substrate, wherein the channel through holes are configured to carry the fluid, forming a plurality of circuits monolithically integrated with the substrate, wherein each circuit of the plurality of circuitries is arranged adjacent a respectively assigned channel through hole, each circuit including a detection electrode and an control circuit coupled to the detection electrode and configured to control access to the detection electrode, wherein each detection electrode is positioned relative to the respectively assigned channel through hole such at least one electrical property of the fluid flowing through the channel through hole can be detected.

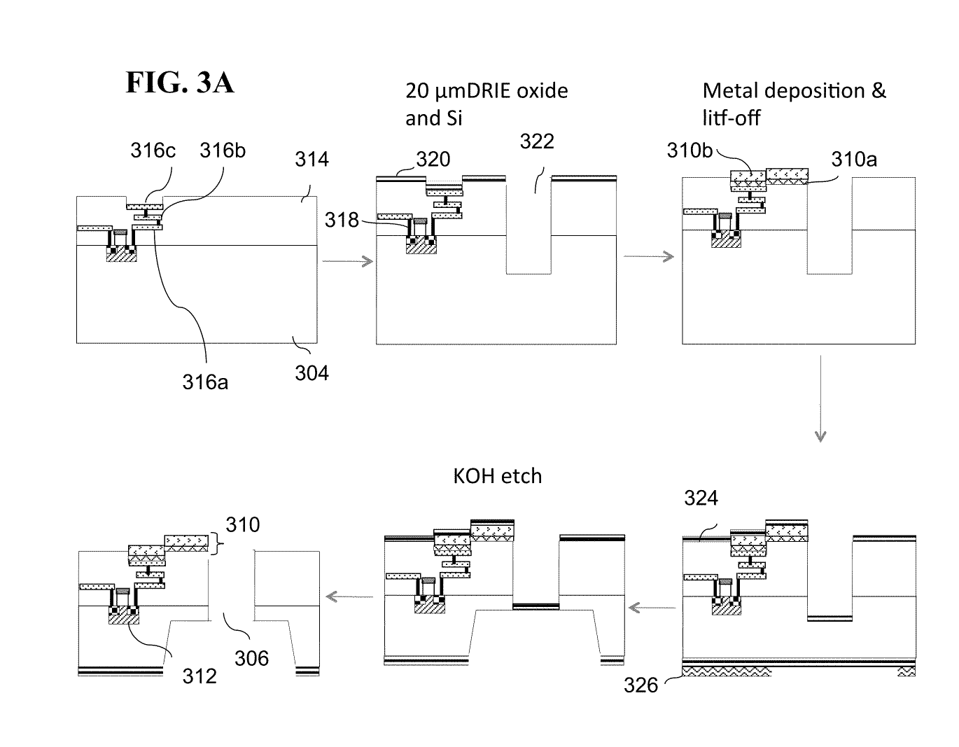

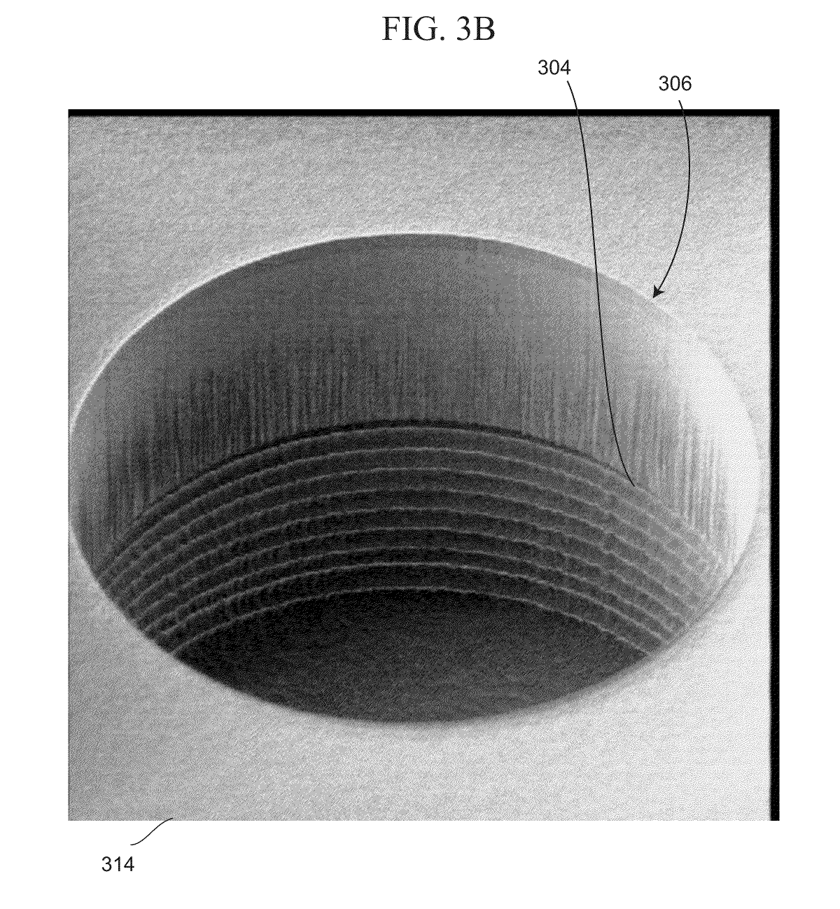

FIG. 3 shows a flow schematic illustrating a method to fabricate the apparatus for detecting particles according to various embodiments. In FIG. 3, the control circuit 312 is formed before forming the channel through hole 306. In various embodiments, the channel through hole 306 may be formed before forming the control circuit 312.

In FIG. 3A, a control circuit 312 such as a metal oxide field effect transistor is first formed together on the substrate 304. Associated metallization layers 316a, 316b and 316c as well as vias 318 are formed on an overlying layer 314 deposited on substrate 304. Layer 314 is an insulating layer comprising of multiple film stacks such as silicon dioxide (SiO₂) and silicon nitride (Si₃N₄). A trench 322 is formed by depositing a first masking layer 320 and then using an etching method such as deep reactive ion etching. The first masking layer 320 is then removed. The detection electrode 310 comprising two layers 310a and 310b is then formed using a second masking layer (not shown) and lift-off. A protective layer 324 is then deposited followed by a third masking layer 326. A backside wet etch followed by deep reactive ion etching is then used to form the assigned channel through hole 306. FIG. 3B shows a scanning electron microscopy image of a channel through hole 306 extending across the silicon substrate 304 and the overlying layer 314.

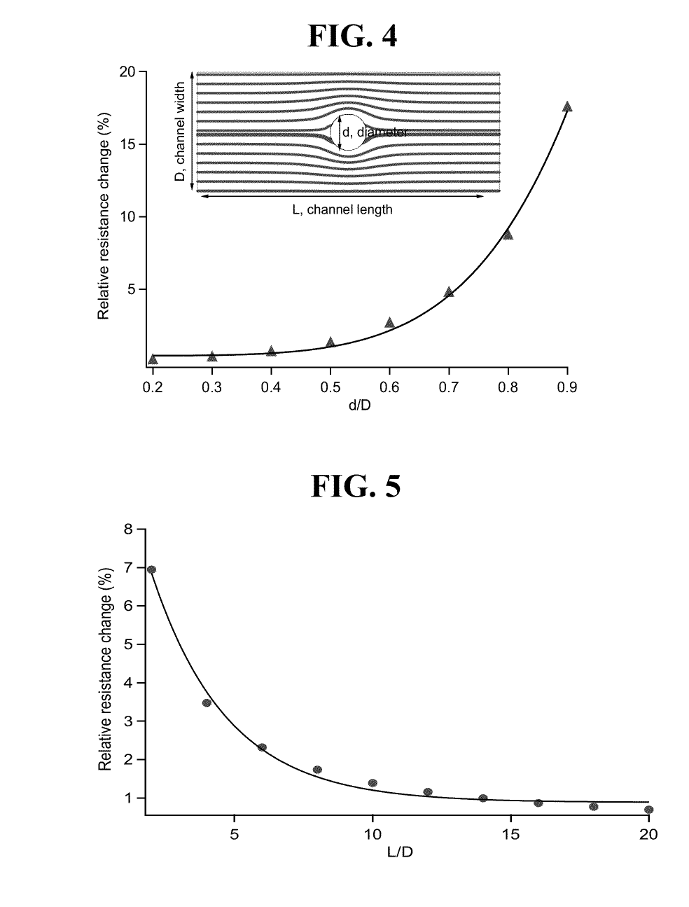

FIG. 4 is a graph plotting the relative resistance change against the ratio of the diameter of the particle and the diameter of the channel. The experimental results are indicated as triangular points and are compared with theoretical prediction. FIG. 4 shows that the experimental results agrees the theoretical prediction. The inset of FIG. 4 shows an electrical stream line plot of a particle in a channel. FIG. 4 shows that it is possible to determine the size of particles passing through the channel through holes by measuring the relative resistance change.

FIG. 5 is a graph plotting the relative resistance change against the ratio of the aspect ratio of the channel through hole (indicated as a ratio of the length of the channel through hole to the diameter of the channel through hole). FIG. 5 shows that a greater resistance change may be obtained by using a channel through hole in which the diameter is low relative to the length.

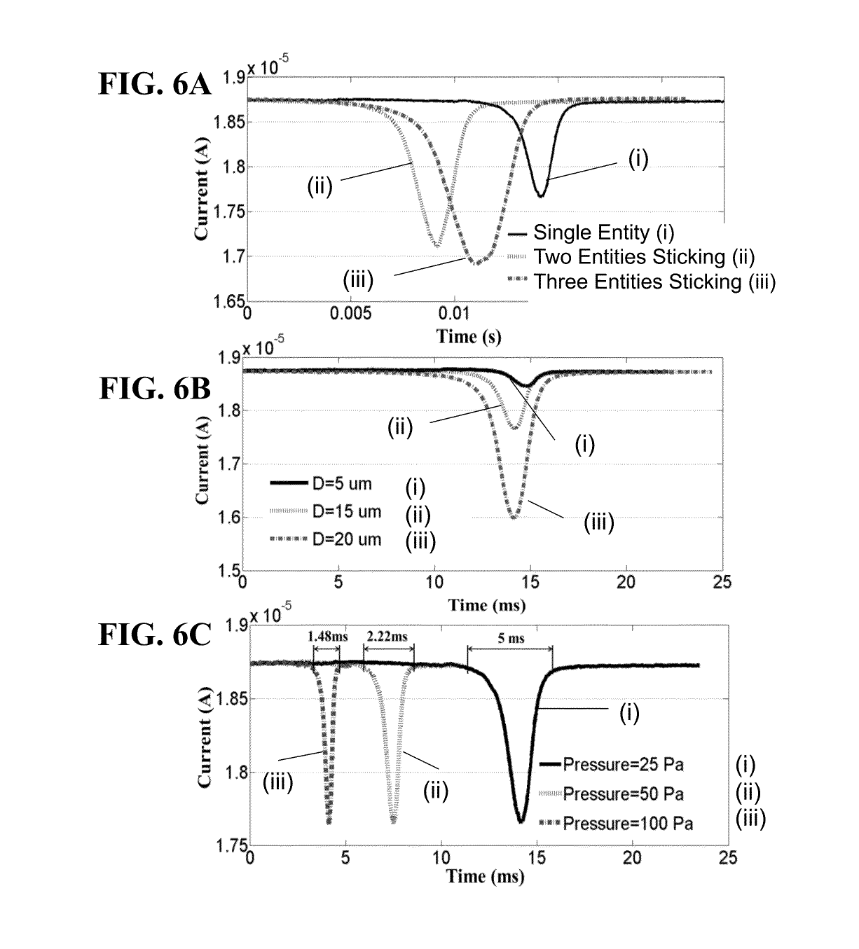

FIG. 6A is a plot showing pulse profiles of particles consisting of a single entity, two entities and three entities. FIG. 6A illustrates that the current passing through the transistor decreases by much more with a particle consisting of a larger number of entities. The pulse width also increases with the number of entities. FIG. 6B is a plot showing pulse profiles of particles having different sizes. FIG. 6B illustrates that the current passing through the transistor decreases by much more with a larger particle. The pulse width also increases with a larger particle size. FIG. 6C is a plot showing pulse profiles of particles in fluids of different pressures. FIG. 6C shows that the pulse width of particles decreases with a higher pressure.

For illustration purposes only and not as a limiting example, the term “substantially” may be quantified as a variance of +/−5% from the exact or actual. For example, the phrase “A is (at least) substantially the same as B” may encompass embodiments where A is exactly the same as B, or where A may be within a variance of +/−5%, for example of a value, of B, or vice versa.

In the context of various embodiments, the term “about” as applied to a numeric value encompasses the exact value and a variance of +/−5% of the value.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. An apparatus for detecting particles in a fluid comprising:
a substrate;
a plurality of channel through holes extending through the substrate, wherein the channel through holes are configured to carry the fluid;
a plurality of circuits monolithically integrated with the substrate, wherein each circuit of the plurality of circuitries is arranged adjacent a respectively assigned channel through hole, each circuit comprising:
a detection electrode; and
an control circuit coupled to the detection electrode and configured to control access to the detection electrode;
wherein each detection electrode is positioned relative to the respectively assigned channel through hole such at least one electrical property of the fluid flowing through the channel through hole can be detected.

2. The apparatus for detecting particles in a fluid according to claim 1, wherein the electrical property is an electrical property representative of an amount of the particles to be detected in the fluid.

3. The apparatus for detecting particles in a fluid according to claim 1, wherein each control circuit comprises a transistor coupled to the respective detection electrode such that a change of the at least one electrical property of the fluid flowing through the channel through hole causes a change of a current flow through the transistor.

4. The apparatus for detecting particles in a fluid according to claim 1, wherein each control circuit comprises a transistor coupled to the respective detection electrode such that a change of the at least one electrical property of the fluid flowing through the channel through hole causes a disturbance of the current flow through the transistor.

5. The apparatus for detecting particles in a fluid according to claim 1, wherein the channel through hole extends substantially perpendicularly from a first surface of the substrate to a second surface of the substrate opposite the first surface of the substrate.

6. The apparatus for detecting particles in a fluid according to claim 3, wherein the transistor is a metal oxide field effect transistor.

7. The apparatus for detecting particles in a fluid according to claim 3,
wherein the transistor comprises a control terminal, a first controlled terminal and a second controlled terminal; and
wherein the first controlled terminal of the transistor is electrically connected to the detection electrode.

8. The apparatus for detecting particles in a fluid according to claim 1, wherein the detection electrode comprises a first layer and a second layer stacked above one another.

9. The apparatus for detecting particles in a fluid according to claim 1, wherein the particles are biological entities.

10. The apparatus for detecting particles in a fluid according to claim 9, wherein the biological entities are biological cells.

11. The apparatus for detecting particles in a fluid according to claim 4, wherein each disturbance of the current flow through the transistor is representative for a predetermined number of particles in the fluid.

12. The apparatus for detecting particles in a fluid according to claim 1, wherein the substrate comprises silicon.

13. The apparatus for counting particles in a fluid according to claim 1, wherein the plurality of channel through holes are arranged in a two dimensional array along the substrate.

14. A method of fabricating an apparatus for detecting particles in a fluid, the method comprising:
forming a plurality of channel through holes extending through a substrate, wherein the channel through holes are configured to carry the fluid;
forming a plurality of circuits monolithically integrated with the substrate, wherein each circuit of the plurality of circuitries is arranged adjacent a respectively assigned channel through hole, each circuit comprising:
a detection electrode; and
a control circuit coupled to the detection electrode and configured to control access to the detection electrode;
wherein each detection electrode is positioned relative to the respectively assigned channel through hole such at least one electrical property of the fluid flowing through the channel through hole can be detected.

15. The method of fabricating an apparatus for detecting particles in a fluid according to claim 14 wherein the electrical property is an electrical property representative of an amount of the particles to be detected in the fluid.

16. The method of fabricating an apparatus for detecting particles in a fluid according to claim 14 wherein each control circuit comprises a transistor coupled to the respective detection electrode such that a change of the at least one electrical property of the fluid flowing through the channel through hole causes a change of a current flow through the transistor.

17. The method of fabricating an apparatus for detecting particles in a fluid according to claim 14, wherein each control circuit comprises a transistor coupled to the respective detection electrode such that a change of the at least one electrical property of the fluid flowing through the channel through hole causes a disturbance of the current flow through the transistor.

18. The method of fabricating an apparatus for detecting particles in a fluid according to claim 14, wherein the channel through hole extends substantially perpendicularly from a first surface of the substrate to a second surface of the substrate opposite the first surface of the substrate.

19. The method of fabricating an apparatus for detecting particles in a fluid according to claim 16, wherein the transistor is a metal oxide field effect transistor.

20. The method of fabricating an apparatus for detecting particles in a fluid according to claims 16,
wherein the transistor comprises a control terminal, a first controlled terminal and a second controlled terminal; and
wherein the first controlled terminal of the transistor is electrically connected to the detection electrode.

21. The method of fabricating an apparatus for detecting particles in a fluid according to claim 14, wherein the detection electrode comprises a first layer and a second layer stacked above one another.

22. The method of fabricating an apparatus for detecting particles in a fluid according to claim 14, wherein the particles are biological entities.

23. The method of fabricating an apparatus for detecting particles in a fluid according to claim 22, wherein the biological entities are biological cells.

24. The method of fabricating an apparatus for detecting particles in a fluid according to claim 17, wherein each disturbance of the current flow through the transistor is representative for a predetermined number of particles in the fluid.

25. The method of fabricating an apparatus for detecting particles in a fluid according to claim 14, wherein the substrate comprises silicon.

26. The method of fabricating an apparatus for detecting particles in a fluid according to claim 14, wherein the plurality of channel through holes are arranged in a two dimensional array along the substrate.
